(19) United States
(12) Patent Application Publication
(10) Pub. No.: US 2011/0305084 A1
(43) Pub. Date: Dec. 15, 2011

(54) NON-VOLATILE MEMORY DEVICE

(75) Inventor: Myoung-Kyu PARK, Yongin-si (KR)

(73) Assignee: SAMSUNG ELECTRONICS CO., LTD., Suwon-si (KR)

(21) Appl. No.: 13/050,398

(22) Filed: Mar. 17, 2011

(30) Foreign Application Priority Data
Jun. 9, 2010 (KR) 10-2010-0054430

(51) Int. Cl. G11C 14/00; H01L 29/94

(52) U.S. Cl. 365/185.08; 257/298; 257/E29.345

(57) ABSTRACT

A non-volatile memory device includes; a first well having a first impurity concentration formed in a first region of a semiconductor substrate, a second well having a second impurity concentration different from the first impurity concentration formed in a second region of the semiconductor substrate, an access transistor with floating gate formed on the first region, and a control Metal Oxide Semiconductor (MOS) capacitor with one electrode formed on the second region. The floating gate and the one electrode are formed from respective portions of a unitary gate line extending across the first and second regions

### CROSS-REFERENCE TO RELATED APPLICATIONS

This application claims priority to Korean Patent Application No. 10-2010-0054430 filed on Jun. 9, 2010, the subject matter of which is hereby incorporated by reference in its entirety.

### BACKGROUND OF THE INVENTION

The present inventive concept relates generally to non-volatile memory devices.

Various types of memory cell structures have been developed for use within Electrically Erasable Programmable Read-Only Memories (EEPROMs). The EEPROM is one class of non-volatile memory that is capable of being electrically programmed and erased while also being capable of retaining stored data in the absence of applied power. The overall size of many contemporary electronic devices may be reduced using a family of fabrication processes and technologies that are used to manufacture so-called System On Chip (SOC) products. A SOC generally provides the functionality previously ascribed to number a number of different semiconductor devices, albeit in a single semiconductor chip. Various SOCs incorporate EEPROMs having a single gate structure.

In general operation, an EEPROM cell is programmed using a defined program voltage, and is erased using a defined erase voltage. The program voltage and erase voltage typically have different levels, so an additional voltage supply is necessary. The conventional requirement to provide this additional voltage supply results in an increase in the overall size of a cell driving unit.

### SUMMARY OF THE INVENTION

Embodiments of the inventive concept provide a non-volatile memory device capable of being programmed and erased using a similar voltage.

According to one aspect of the inventive concept, there is provided a non-volatile memory device comprising; a first well having a first impurity concentration and formed in a first region of a semiconductor substrate, a second well having a second impurity concentration different from the first impurity concentration and formed in a second region of the semiconductor substrate, an access transistor with floating gate formed on the first region, and a control Metal Oxide Semiconductor (MOS) capacitor with one electrode formed on the second region, wherein the floating gate and the one electrode are formed from respective portions of a unitary gate line extending across the first and second regions.

According to another aspect of the inventive concept, there is provided a method of operating a nonvolatile memory device, the nonvolatile memory device comprising; a first well having a first impurity concentration formed in a first region of a semiconductor substrate, a second well having a second impurity concentration different from the first impurity concentration formed in a second region of the semiconductor substrate, an access transistor with floating gate formed on the first region, a control Metal Oxide Semiconductor (MOS) capacitor with one electrode formed on the second region, wherein the floating gate and the one electrode are formed from respective portions of a unitary gate line extending across the first and second regions, source/drain regions formed in the first channel region on opposing sides of the floating gate, a first region well tap formed in the first region spaced apart from the source/drain regions, opposing impurity regions formed on opposing sides of the one electrode in the second well, a second region well tap formed in the second region spaced apart from the opposing regions, and a third region well tap formed in a third region of the semiconductor substrate outside the first and second regions. The method comprises; during a programming operation, applying a first voltage to the opposing impurity regions, the second region well tap, and the third region well tap while applying ground voltage to the source/drain regions and the first region well tap, and during a erase operation, applying a second voltage substantially equal to the first voltage to the source/drain regions, the first region well tap, and the third region well tap while applying ground voltage to the opposing impurity regions and the second region well tap.

According to another aspect of the inventive concept, there is provided a system comprising a memory controller configured to control the execution of programming and erase operations within a memory, the memory comprising at least one non-volatile memory device comprising; a first well having a first impurity concentration formed in a first region of a semiconductor substrate, a second well having a second impurity concentration different from the first impurity concentration formed in a second region of the semiconductor substrate, an access transistor with floating gate formed on the first region, and a control Metal Oxide Semiconductor (MOS) capacitor with one electrode formed on the second region, wherein the floating gate and the one electrode are formed from respective portions of a unitary gate line extending across the first and second regions.

### BRIEF DESCRIPTION OF THE DRAWINGS

The above and other features and advantages of the inventive concept will become more apparent upon consideration of certain embodiments thereof described below with reference to the attached drawings in which:

FIG. 1 is a unit memory cell layout for a non-volatile memory device in accordance with an embodiment of the inventive concept.

FIG. 2 is a cross sectional view taken along lines 2A-2A′ and 2B-2B′ of FIG. 1.

FIGS. 3 and 4 are graphs further explaining the operation of a non-volatile memory device in accordance with an embodiment of the inventive concept.

FIGS. 5 to 7 illustrate general systems that may incorporate one or more non-volatile memory devices in accordance with an embodiment of the inventive concept.

### DETAILED DESCRIPTION

Advantages and features of the inventive concept, as well as methods of accomplishing the same may be understood by reference to the following detailed description of preferred embodiments and the accompanying drawings. The inventive concept may, however, be embodied in many different forms and should not be construed as being limited to only the embodiments set forth herein. Rather, these embodiments are provided so that this disclosure will be thorough and complete and will fully convey the concept of the inventive concept to those skilled in the art. The scope of the inventive concept is defined by the appended claims. Throughout the written description and drawings similar reference numbers and labels are used to denote similar or like elements. The relative size and geometry of the layers and regions illustrated in the drawings may be exaggerated for clarity.

As used herein, the term “and/or” includes any and all combinations of one or more of the associated listed items. The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, certain non-volatile memory devices in accordance with embodiment(s) of the inventive concept will be described in some additional detail.

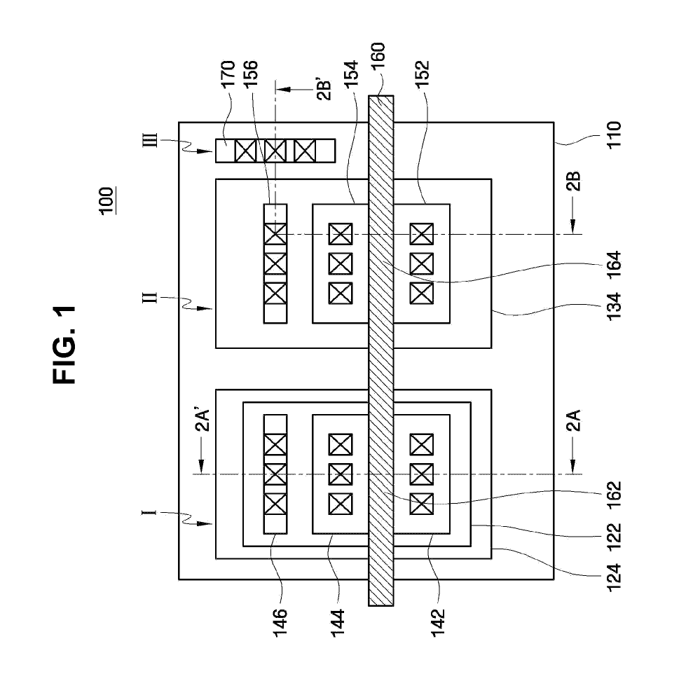

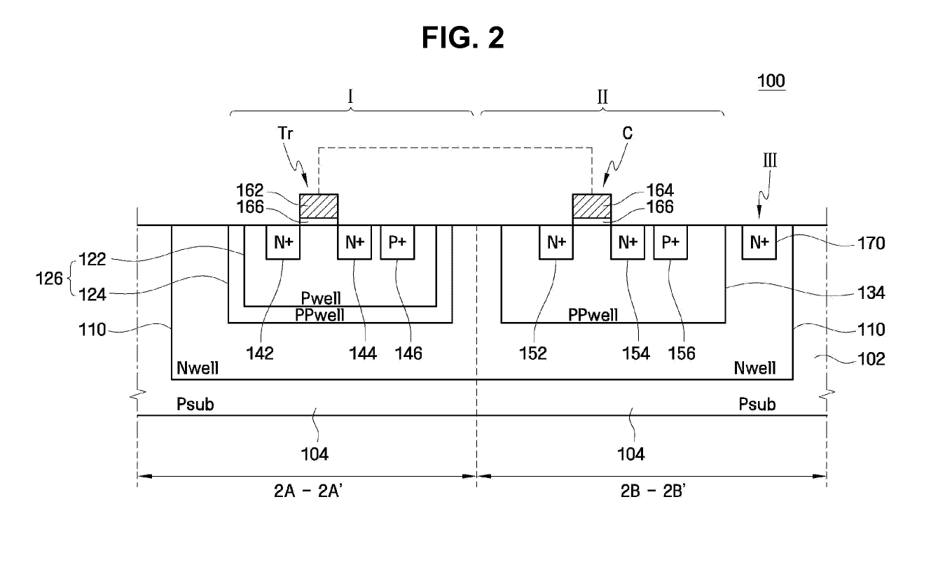

FIG. 1 illustrates a unit memory cell layout for a non-volatile memory device in accordance with an embodiment of the inventive concept. FIG. 2 is a cross-sectional view taken along lines 2A-2A′ and 2B-2B′ of FIG. 1. Although an EEPROM is described as one example of a non-volatile memory device that may be realized according to the inventive concept, those skilled in the art will recognize that other types of non-volatile memory may be similarly realized by extending the illustrative teachings set forth herein.

Referring collectively to FIGS. 1 and 2, a unit memory cell 100 of the non-volatile memory device in accordance with an embodiment of the inventive concept comprises a semiconductor substrate 102, a gate line 160, a deep well 110, a first well 126, a second well 134, an access transistor Tr, a control metal oxide semiconductor (MOS) capacitor C and first to third region well taps 146, 156 and 170.

The semiconductor substrate 102 may be of first conductivity type (e.g., P type). An active region 104 of the semiconductor substrate 102 may include a first region I in which the access transistor Tr is formed, a second region II in which a control MOS capacitor C having a control gate 164 is formed, and a third region III in which a third region well tap 170 is formed. Further, the first region I and the second region II may be separated from each other as shown in FIGS. 1 and 2.

The unitary gate line 160 extends over the first region I and second region II may of the semiconductor substrate 102. A first portion of the unitary gate line 160 forms a floating gate 162 of the access transistor Tr that will be described hereafter in some additional detail, and a second portion of the unitary gate line 160 forms a control gate 164 serving as an electrode of the control MOS capacitor C that will also be described hereafter in some additional detail. With this configuration, the floating gate 162 of the access transistor Tr and the control gate 164 (electrode) of the control MOS capacitor C are electrically equivalent in that a voltage (current, capacitance, etc.) signal applied to the gate line 160 will be commonly applied to the floating gate 162 and the capacitor electrode.

The deep well 110 may be second conductivity type (e.g., N type). The deep well 110 may be formed to include the first, second and third regions (I, II and III) of the active region 104 of the semiconductor substrate 102.

In the illustrated example of FIG. 2, the first well 126 is formed in the deep well 110 of the first region I of the semiconductor substrate 102. The first well 126 includes a first channel well 122 of first conductivity type having a first impurity concentration and a first pocket well 124 of first conductivity type having a second impurity concentration. In one embodiment of the inventive concept, the first channel well 122 may be formed within the first pocket well 124, as shown in FIG. 2. Further, the first impurity concentration may be greater than the second impurity concentration.

Also in the illustrated example of FIG. 2, the second well 134 is formed in the deep well 110 of the second region II of the semiconductor substrate 102. The second well 134 includes a second pocket well 134 of a first conductivity type having a third impurity concentration, that may be equal to the second impurity concentration. That is, the second pocket well 134 may have an impurity concentration equal to that of the first pocket well 124 and less than that of the first channel well 122. Thus, in sum, the impurity concentration of the first well 126 may be greater than the impurity concentration of the second well 134.

The access transistor Tr is formed by the floating gate 162 (the first portion of the gate line 160) and source/drain regions 142 and 144 formed on opposing sides of the floating gate 162 within the first channel well 122. FIG. 2 illustrates an example in which the source/drain regions 142 and 144 are formed of second (e.g., N+) type impurity regions and the access transistor Tr is configured as an NMOS transistor.

The control MOS capacitor C includes the one electrode (the control gate 164 and second portion of the gate line 160) and another electrode. Impurity regions 152 and 154 are formed on opposing sides of the control gate 164 within the second pocket well 134, and a gate insulating film 166 is interposed between the doped substrate and the control gate 164. That is, within the example illustrated in FIG. 2, second conductivity type (N+) impurity regions 152 and 154 are formed in the second pocket well 134 of the second region II.

The first, second and third region well taps 146, 156 and 170 are respectively formed in the first, second and third regions (I, II and III) of the active region 104 of the semiconductor substrate 102. That is, the first region well tap 146 having the same conductivity type as the first channel well 122 and an impurity concentration greater than that of the first channel well 122 is formed apart from the source and drain regions 142 and 144 in the first channel well 122. In the illustrated example of FIG. 2, the first region well tap 146 is formed in the first channel well 122 of first conductivity type (e.g., P type) and, thus, the first region well tap 146 may be formed of a P+ type impurity region.

Further, the second region well tap 156 having the same conductivity type as that of the second pocket well 134 and an impurity concentration greater than that of the second pocket well 134 is formed apart from the impurity regions 152 and 154 in the second pocket well 134. In the illustrated example of FIG. 2, the second region well tap 156 is formed in the second pocket well 134 of a first conductivity type (e.g., P type) and, thus, the second region well tap 156 may be formed of a P+ type impurity region.

Finally, the third region well tap 170 used to apply a voltage to the bulk of the semiconductor substrate 102 is formed in the third region III apart from the first region I and the second region II in the active region 104.

The third region well tap 170 may be formed of an impurity diffusion region having the same conductivity type as that of the surrounding substrate region. The impurity concentration of the third region well tap 170 may be greater than that of the surrounding substrate region. In the illustrated example of FIG. the deep well 110 of second conductivity type is formed in the active region 104 of the semiconductor substrate 102 of first conductivity type. Accordingly, the third region well tap 170 is also formed of first conductivity type (e.g., N+), albeit with a greater impurity concentration.

The first and second region well taps 146 and 156 ensure the stable execution of erase and programming operations. That is, an erase operation may be stably performed by applying an erase voltage to the first region well tap 146 at the same time as an erase voltage having a relatively higher level is applied to the source and drain regions 142 and 144. Similarly, a programming operation may be stably performed by applying a program voltage to the second region well tap 156 at the same time as a program voltage having a relatively higher level is applied to the impurity regions 152 and 154. Further, the third region well tap 170 prevents junction breakdown that might otherwise occur between the source and drain regions 142 and 144 and the first channel well 122 or between the impurity regions 152 and 154 and the second pocket well 134 when the program voltage or erase voltage is applied. Moreover, the third region well tap 170 prevents turn-ON of a PN diode junction formed between the wells or well taps of first conductivity type and the deep well 110 of second conductivity type.

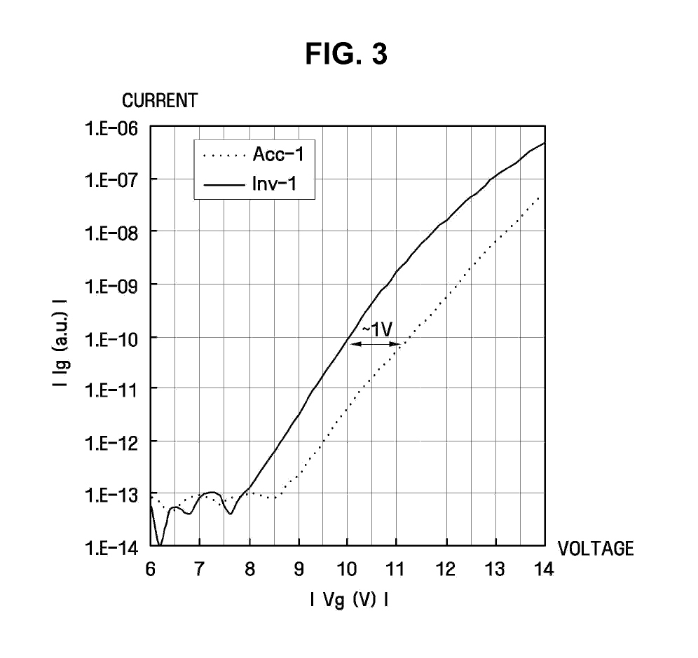

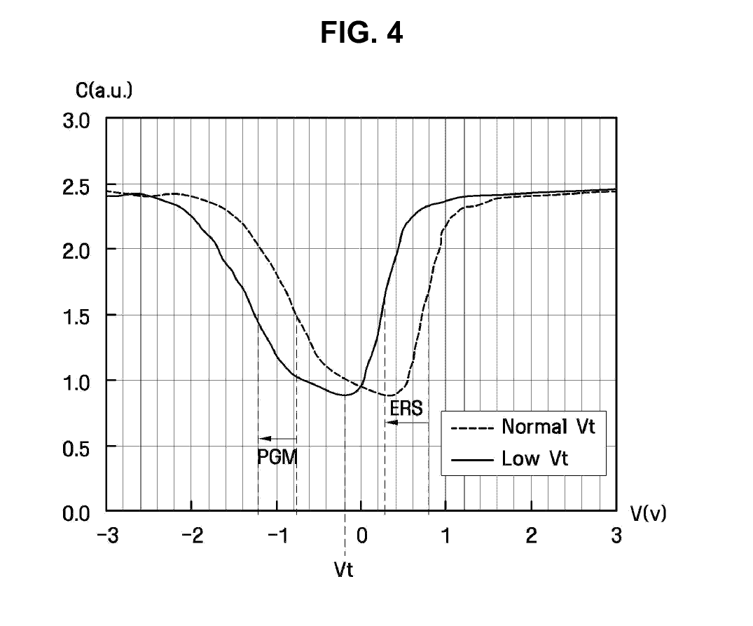

The operation of an exemplary non-volatile memory device in accordance with an embodiment of the inventive concept will be described with reference to FIGS. 2, 3 and 4, wherein FIGS. 3 and 4 are graphs further explaining the operation of the non-volatile memory device.

During a programming operation, a first voltage is applied to the impurity regions 152 and 154 and the second region well tap 156 in the second region II and the third region well tap 170, and ground voltage is applied to the source and drain regions 142 and 144 and the first region well tap 146 in the first region I. When a program voltage is applied, charge moves to the floating gate 162 from the semiconductor substrate 102 through the access transistor Tr consistent with the conventionally understood Fowler-Nordheim tunneling effect. Consequently, charge is stored in the floating gate 162 as the result of the programming operation. Such movement of charge is related to a gate current in an inversion mode of the access transistor Tr.

On the other hand, during an erase operation, a second voltage is applied to the first region well tap 146 and the source and drain regions 142 and 144 of the access transistor Tr in the first region I and the third region well tap 170, and ground voltage is applied to the second region well tap 156 and the impurity regions 152 and 154 in the second region II. Accordingly, charge move to the semiconductor substrate 102 from the floating gate 162 via the access transistor Tr. Consequently, the charge stored on the floating gate 162 is removed (or erased). Such movement of charge is related to a gate current in an accumulation mode of the access transistor Tr.

According to the foregoing operations, if the first well 126 and the second well 134 have the same impurity concentration (e.g., if a second channel well (not shown) is formed to include the impurity regions 152 and 154 in FIG. 2, or if the first channel well 122 is omitted in FIG. 2) unlike the non-volatile memory device in accordance with the embodiment of the present inventive concept, the first voltage used during the program operation should be less than the second voltage used during the erase operation. In one possible example, the first voltage may be 16 V and the second voltage may be 17 V.

This difference between the first voltage and the second voltage is caused by the gate currents associated with different modes flowing in the access transistor Tr during the programming and erase operations. That is, as described above, the inversion mode gate current flows in the access transistor Tr during the programming operation, and the accumulation mode gate current flows in the access transistor Tr during the erase operation. As further illustrated in FIG. 3, the inversion mode gate current is less than the accumulation mode gate current at the same gate voltage, and an additional voltage of about 1 V is required to achieve the same current flow. This outcome may be attributed to a flat band voltage difference (about 1 V) between the inversion mode and the accumulation mode of the access transistor Tr. Accordingly, the second voltage used during the erase operation should be about 1 V greater than the first voltage used during the programming operation.

However, in non-volatile memory devices in accordance with embodiments of the inventive concept, the first well 126 formed in the first region I of the semiconductor substrate 102 in which the access transistor Tr is formed includes the first channel well 122 and the first pocket well 124, and the second well 134 formed in the second region II of the semiconductor substrate 102 in which the control MOS capacitor C is formed includes only the second pocket well 134. Accordingly, the impurity concentration of the first well 126 is greater than that of the second pocket well 134.

When the impurity concentration of the second well 134 is less than that of the first well 126, the C-V characteristic curve of the control MOS capacitor C is shifted by about 0.5 V in the negative direction as shown in FIG. 4. In this case, a threshold voltage (Vt) for the control MOS capacitor C will range from between about 0 to 0.5 V. (Here, a minus sign is omitted because it means a voltage application direction, as shown in FIG. 4). If the C-V characteristic curve of the control MOS capacitor C is shifted by about 0.5 V in the negative direction, the capacitance of the control MOS capacitor C decreases by the same range. Accordingly, during the programming operation (see PGM of FIG. 4), a program voltage is required that is increased by about 0.5 V, as compared to the conventional example in which the first well 126 and the second well 134 have the same impurity concentration in order to maintain the same capacitance.

On the other hand, during an erase operation (see ERS of FIG. 4), an erase voltage is required that is decreased by about 0.5 V, as compared to the conventional case in which the first well 126 and the second well 134 have the same impurity concentration in order to maintain the same capacitance. Accordingly, in a non-volatile memory device in accordance with an embodiment of the inventive concept, the programming and erase operations may be performed by applying a common voltage, serving as both the first voltage during the programming operation and the second voltage during the erase operation. Thus, the different first and second voltages required by the conventional case in which the first well 126 and the second well 134 have the same impurity concentration is alleviated, along with the commensurate requirement of providing an additional voltage source. As a result, semiconductor products designed and operated in accordance with an embodiment of the inventive concept may be reduced in overall size.

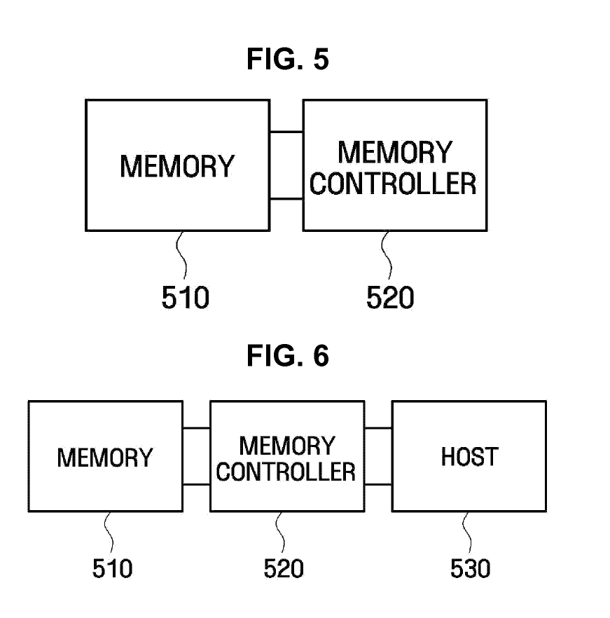

FIGS. 5, 6 and 7 illustrate certain application examples for systems capable if incorporating one or more non-volatile memory device(s) in accordance with embodiments of the inventive concept.

In the example of FIG. 5, a system may include a memory 510 and a memory controller 520 connected to the memory 510. In this case, the memory 510 may be the non-volatile memory device in accordance with the embodiment of the present inventive concept, in which program and erase voltages having the same level are applied to a memory cell. The memory controller 520 may provide, to the memory 510, an input signal for controlling the operation of the memory 510, e.g., a command signal and address signal for controlling a read and write operation.

In the example of FIG. 6, a system may include the memory 510, the memory controller 520 and a host system 530. In this case, the host system 530 is connected to the memory controller 520 via a bus or the like, and provides a control signal to the memory controller 520 so that the memory controller 520 can control the operation of the memory 510. Although the memory controller 520 is interposed between the memory 510 and the host system 530 in the example of FIG. 6, it is not limited thereto, and the memory controller 520 can be selectively omitted in another example.

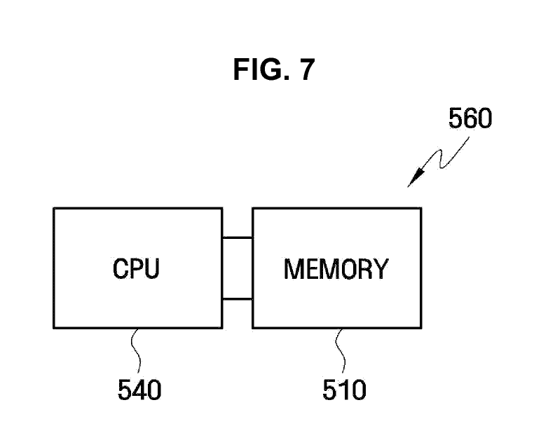

In the example of FIG. 7, a computer system 560 may include a Central Processing Unit (CPU) 540 and a memory 510. In the computer system 560, the memory 510 may be connected to the CPU 540 directly or via a general computer bus architecture, and may store an Operation System (OS) instruction set, a Basic Input/Output Start-up BIOS) instruction set, an Advanced Configuration and Power Interface (ACPI) instruction set and the like or be used as a mass storage device such as a Solid State Disk (SSD).

Meanwhile, although all components included in the computer system 560 are not shown in FIG. 7 for simplicity, it is not limited thereto. Further, although the memory controller 520 is omitted between the memory 510 and the CPU 540 in the example of FIG. 7, the memory controller 520 may be interposed between the memory 510 and the CPU 540 in another example.

While the present inventive concept has been particularly shown and described with reference to exemplary embodiments thereof, it will be understood by those of ordinary skill in the art that various changes in form and detail may be made therein without departing from the scope of the inventive concept as defined by the following claims. The exemplary embodiments should be considered in a descriptive sense only and not for purposes of limitation.

What is claimed is:

1. A non-volatile memory device comprising:
a first well having a first impurity concentration and formed in a first region of a semiconductor substrate;
a second well having a second impurity concentration different from the first impurity concentration and formed in a second region of the semiconductor substrate;
an access transistor with floating gate formed on the first region, and a control Metal Oxide Semiconductor (MOS) capacitor with one electrode formed on the second region, wherein the floating gate and the one electrode are formed from respective portions of a unitary gate line extending across the first and second regions.

2. The non-volatile memory device of claim 1, further comprising a deep well encompassing the first and second regions.

3. The non-volatile memory device of claim 2, wherein the semiconductor substrate is of first conductivity type, the deep well is of second conductivity type, and the first and second regions are both of first conductivity type.

4. The non-volatile memory device of claim 3, further comprising:
a first pocket well of first conductivity type formed in the first well; and
a first channel well of first conductivity type formed in the first pocket well, wherein the first channel well has an impurity concentration greater than that of the first pocket well.

5. The non-volatile memory device of claim 4, wherein the first pocket well has an impurity concentration substantially equal to the second impurity concentration, and the first impurity concentration is greater than the second impurity concentration.

6. The non-volatile memory device of claim 5, wherein the first conductivity type is P type and the second conductivity type is N type.

7. The non-volatile memory device of claim 5, further comprising:
source/drain regions of second conductivity type formed in the first channel region on opposing sides of the floating gate; and
a first region well tap of first conductivity type formed in the first well and spaced apart from the source/drain regions.

8. The non-volatile memory device of claim 7, further comprising:
opposing impurity regions of second conductivity type formed on opposing sides of the one electrode in the second well; and
a second region well tap of first conductivity type formed in the second well and spaced apart from the opposing regions.

9. The non-volatile memory device of claim 8, further comprising:
a third region well tap of second conductivity type formed in a third region of the semiconductor substrate outside the first and second regions.

10. The non-volatile memory device of claim 9, wherein the third region well tap is formed in the deep well.

11. The non-volatile memory device of claim 1, wherein a threshold voltage of the control MOS capacitor ranges between about 0 to 0.5 V.

12. A method of operating a nonvolatile memory device, the nonvolatile memory device comprising:
a first well having a first impurity concentration formed in a first region of a semiconductor substrate;
a second well having a second impurity concentration different from the first impurity concentration formed in a second region of the semiconductor substrate;
an access transistor with floating gate formed on the first region;
a control Metal Oxide Semiconductor (MOS) capacitor with one electrode formed on the second region, wherein the floating gate and the one electrode are formed from respective portions of a unitary gate line extending across the first and second regions, the method comprising;
source/drain regions formed in the first channel region on opposing sides of the floating gate;
a first region well tap formed in the first region spaced apart from the source/drain regions;
opposing impurity regions formed on opposing sides of the one electrode in the second well;
a second region well tap formed in the second region spaced apart from the opposing regions; and
a third region well tap formed in a third region of the semiconductor substrate outside the first and second regions,
wherein the method comprises:
during a programming operation, applying a first voltage to the opposing impurity regions, the second region well tap, and the third region well tap while applying ground voltage to the source/drain regions and the first region well tap; and
during an erase operation, applying a second voltage substantially equal to the first voltage to the source/drain regions, the first region well tap, and the third region well tap while applying ground voltage to the opposing impurity regions and the second region well tap.

13. The method of claim 12, wherein the nonvolatile memory device further comprises a deep well commonly encompassing at least the first and second regions.

14. The method of claim 13, wherein the semiconductor substrate is of first conductivity type, the deep well is of second conductivity type, and the first and second regions are both of first conductivity type, the source/drain regions and opposing impurity regions are of second conductivity type, the first region well tap and the second regions well tap are of first conductivity type, and the third region well tap is of second conductivity type.

15. The method of claim 12, wherein a threshold voltage of the control MOS capacitor ranges between about 0 to 0.5 V.

16. A system comprising a memory controller configured to control the execution of programming and erase operations within a memory, the memory comprising at least one non-volatile memory device comprising:
a first well having a first impurity concentration formed in a first region of a semiconductor substrate;
a second well having a second impurity concentration different from the first impurity concentration formed in a second region of the semiconductor substrate; and
an access transistor with floating gate formed on the first region, and a control Metal Oxide Semiconductor (MOS) capacitor with one electrode formed on the second region, wherein the floating gate and the one electrode are formed from respective portions of a unitary gate line extending across the first and second regions.

17. The system of claim 16, wherein a threshold voltage of the control MOS capacitor ranges between about 0 to 0.5 V.

18. The system of claim 16, wherein the memory controller is a Central Processing Unit (CPU).

19. The system of claim 16, wherein the memory comprises a plurality of nonvolatile memory devices configured to operate as a Solid State Disk (SSD).

20. The system of claim 16, wherein the memory controller is configured to function as a data channel between the memory and a host.
